(19) United States
(12) Patent Application Publication
(10) Pub. No.: US 2011/0204438 A1
(43) Pub. Date: Aug. 25, 2011

(54) SEMICONDUCTOR DEVICE

(75) Inventor: Koji TANIGUCHI, Tokyo (JP)

(73) Assignee: ELPIDA MEMORY, INC., Tokyo (JP)

(21) Appl. No.: 13/030,633

(22) Filed: Feb. 18, 2011

(30) Foreign Application Priority Data
Feb. 22, 2010 (JP) 2010-036472

(51) Int. Cl. H01L 29/78

(52) U.S. Cl. 257/331; 257/332; 257/E29.262

(57) ABSTRACT

A semiconductor device may include, but is not limited to: a semiconductor substrate; a first insulating film; a second insulating film; a first gate electrode; a second gate electrode; and a first semiconductor region. The semiconductor substrate has first and second grooves crossing each other in plan view. The first insulating film covers an inner surface of the first groove. The second insulating film covers an inner surface of the second groove. The first gate electrode fills at least a bottom portion of the first groove. The second gate electrode fills at least a bottom portion of the second groove. The first semiconductor region is positioned in the semiconductor substrate. The first semiconductor region contains a first impurity. The first semiconductor region is adjacent to a first portion of the second insulating film. The first portion of the second insulating film covers at least a bottom region of the second groove.

### BACKGROUND OF THE INVENTION

1. Field of the Invention

The present invention relates to a semiconductor device.

Priority is claimed on Japanese Patent Application No. 2010-036472, filed Feb. 22, 2010, the content of which is incorporated herein by reference.

2. Description of the Related Art

Recently, with miniaturization of DRAM (Dynamic Random Access Memory) cells, the gate length of access transistors in a cell array (hereinafter, “cell transistors”) has been required to be shortened. However, as the gate length becomes shorter, the short channel effect becomes more significant, thereby causing an increase in sub-threshold current, and therefore causing a decrease in threshold voltage (Vth). If a substrate concentration is increased in order to prevent a reduction in a threshold voltage, junction leakage increases, thereby causing deterioration of the refresh characteristics of a DRAM.

To solve the above problems, Japanese Patent Laid-Open Publication No. 2008-300843 discloses a memory device including a trench gate transistor (which is also called a recessed channel transistor) as a memory cell transistor. Specifically, a gate insulating film is formed so as to cover an inner surface of a groove formed in a semiconductor substrate. Then, a gate electrode is formed over the gate insulating film so as to fill up the groove. Then, source and/or drain regions are formed in surface regions of the semiconductor substrate, which are adjacent to the gate electrode. Thus, the trench gate transistor is formed. The trench gate transistor achieves the sufficient effective channel length (i.e., the gate length), and thereby has been used to reduce the size of the DRAM cell transistor.

Generally, a voltage generation circuit is generally used in semiconductor integrated circuits to generate a lower and more stable voltage than a power voltage. Japanese Patent Laid-Open Publication No. 2006-041175 discloses technique of including, in an integrated circuit, a capacitor for preventing oscillation of the voltage generation circuit and stabilizing the output voltage. A capacitance value of such a voltage stabilizing capacitor (compensation capacitor) has to be a certain value or more.

A capacitor including a MOS transistor (hereinafter, “MOS capacitor”) is generally used as the above capacitor in an integrated circuit. However, the capacitance of the MOS capacitor depends on a voltage. Therefore, a variation in voltage occasionally causes a great variation in a capacitance value of the MOS capacitor. When an operational condition is such that a capacitance value of the voltage stabilizing capacitor is the minimum, an output voltage might not be able to be stabilized.

For this reason, a transistor, which has the same structure as that of a transistor included in a memory cell, is used as a MOS capacitor that is applied to a voltage stabilizing capacitor in a voltage generation circuit. Thus, the MOS capacitor functions as a compensation capacitor.

However, when a transistor having the same structure as that of a cell transistor in a memory cell is used as a compensation capacitor, the threshold voltage (Vth) of a transistor used as the compensation capacitor is equal to that of a memory cell transistor. For this reason, as an operational voltage of the memory cell is decreased, a sufficient capacitance value of the transistor as the compensation capacitor cannot be achieved.

To achieve a sufficient capacitance value of a MOS capacitor, it can be considered to selectively implant ions only in a necessary region of the transistor with a mask or the like when a transistor as a compensation capacitor is formed, in order to decrease the threshold voltage of the transistor as the compensation capacitor. However, this method requires an additional photomask process, thereby increasing the number of manufacturing processes.

### SUMMARY

In one embodiment, a semiconductor device may include, but is not limited to: a semiconductor substrate; a first insulating film; a second insulating film; a first gate electrode; a second gate electrode; and a first semiconductor region. The semiconductor substrate has first and second grooves crossing each other in plan view. The first insulating film covers an inner surface of the first groove. The second insulating film covers an inner surface of the second groove. The first gate electrode fills at least a bottom portion of the first groove. The second gate electrode fills at least a bottom portion of the second groove. The first semiconductor region is positioned in the semiconductor substrate. The first semiconductor region contains a first impurity. The first semiconductor region is adjacent to a first portion of the second insulating film. The first portion of the second insulating film covers at least a bottom region of the second groove.

In another embodiment, a semiconductor device may include, but is not limited to: a semiconductor substrate; a first transistor structure; and a second transistor structure. The semiconductor substrate has a memory cell region and a peripheral region. The first transistor structure is positioned over the memory cell region. The first transistor structure may include, but is not limited to a first trench gate electrode. The second transistor structure is positioned over the peripheral region. The second transistor structure may include, but is not limited to: a second trench gate electrode; a first semiconductor region; a second semiconductor region; and a third semiconductor region. The second trench gate electrode is positioned in the peripheral region. The first semiconductor region is positioned in the peripheral region. The first semiconductor region contains a first impurity. The first semiconductor region is adjacent to a surface of the semiconductor substrate and the second trench gate electrode. The second semiconductor region is positioned in the peripheral region. The second semiconductor region contains a second impurity. The second semiconductor region is adjacent to the surface of the semiconductor substrate and the second trench gate electrode. The second trench gate electrode is positioned between the first and second semiconductor regions. The third semiconductor region is positioned in the semiconductor substrate. The third semiconductor region contains a third impurity. The third semiconductor region is adjacent to a bottom portion of the second trench gate electrode.

In still another embodiment, a semiconductor device may include, but is not limited to: a semiconductor substrate; an insulating film; a gate electrode; a first semiconductor region; a second semiconductor region; a third semiconductor region; and a channel region. The semiconductor substrate has a groove. The insulating film covers an inner surface of the groove. The gate electrode fills at least a bottom portion of the groove. The first semiconductor region is positioned in the semiconductor substrate. The first semiconductor region contains a first impurity. The first semiconductor region is adjacent to a surface of the semiconductor substrate and the gate electrode. The second semiconductor region is positioned in the semiconductor substrate. The second semiconductor region contains a second impurity. The second semiconductor region is adjacent to the surface of the semiconductor substrate and the gate electrode. The gate electrode is positioned between the first and second semiconductor regions. The third semiconductor region is positioned in the semiconductor substrate. The third semiconductor region contains a third impurity. The third semiconductor region is adjacent to a first portion of the insulating film. The first portion covers at least a bottom region of the groove. The channel region is positioned in the semiconductor substrate. The channel region is adjacent to a second portion of the insulating film. The second portion covers lower side and bottom surfaces of the groove. The channel region connects the first to third semiconductor regions.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a cross-sectional view illustrating a main transistor structure included in a semiconductor device according to a first embodiment of the present invention;

FIG. 1B is a cross-sectional view illustrating a compensation capacitor transistor structure included in the semiconductor device of the first embodiment;

FIG. 1C illustrates a connection relationship among a gate and source and/or drain regions of the compensation capacitor transistor structure of the first embodiment;

FIGS. 2, 3A, 3B, 4A, and 4B illustrate a process flow indicative of a method of manufacturing the semiconductor device of the first embodiment;

FIG. 5 is a circuit block diagram illustrating a configuration of a DRAM including the main transistor structure and the compensation capacitor transistor structure of the first embodiment;

FIG. 6 is a graph illustrating a relationship between a drive voltage and a capacitance value with respect to the main transistor structure and the comparison capacitor transistor structure of the first embodiment;

FIG. 7 is a plan view illustrating a cell transistor structure of the DRAM;

FIG. 8 is a cross-sectional view illustrating part of the cell transistor structure of the DRAM; and

FIG. 9 is a cross-sectional view illustrating part of the comparison capacitor transistor structure of the DRAM.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

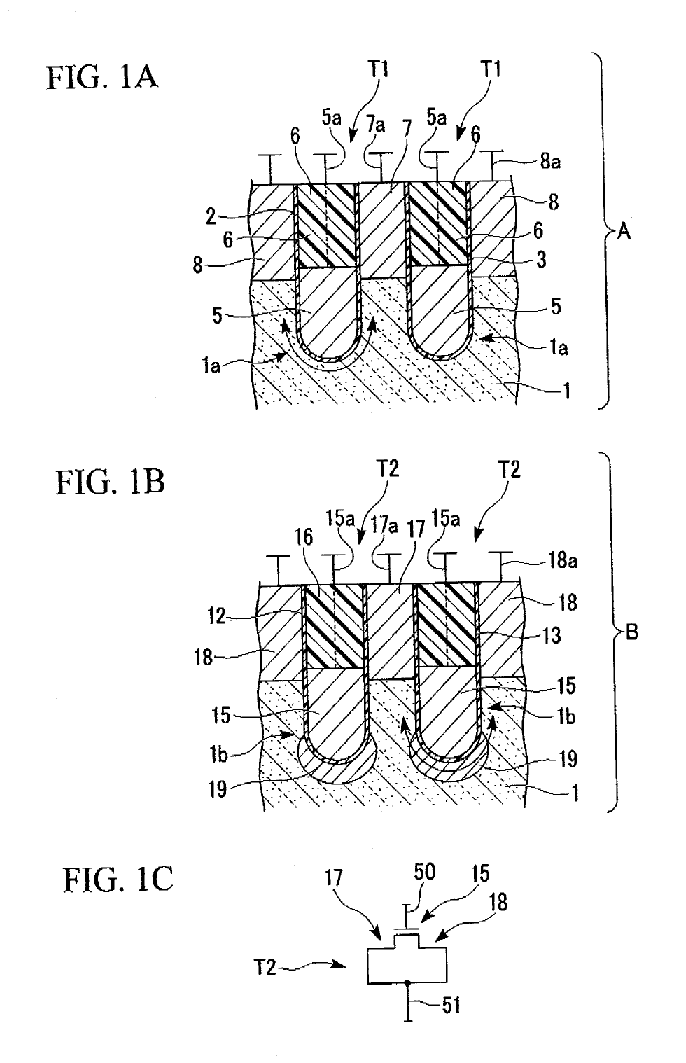

Hereinafter, a semiconductor device according to a first embodiment of the present invention is explained. FIGS. 1A to 1C are cross-sectional views illustrating the semiconductor device according to the first embodiment. FIG. 1A is a cross-sectional view illustrating a main transistor structure formed on part of a semiconductor substrate 1. FIG. 1B is a cross-sectional view illustrating a transistor structure as a compensation capacitor (hereinafter, “compensation capacitor transistor structure”), which is formed on another part of the semiconductor substrate 1.

The semiconductor device of the first embodiment includes a semiconductor substrate 1 having regions A and B in which the main transistor structure and the compensation capacitor transistor structure are formed, respectively. For example, the regions A and B are a memory cell region and a peripheral region, respectively. The main transistor structure is connected to an internal power supply circuit via the compensation capacitor transistor structure. The compensation capacitor transistor structure is positioned between the main transistor structure and the internal power supply circuit. The compensation capacitor transistor structure functions as a compensation capacitor to stabilize the voltage.

In the region A shown in FIG. 1A in which the main transistor structure is formed, multiple first grooves 2 are formed at a predetermined interval in the semiconductor substrate 1. Each first groove 2 has a predetermined depth and a predetermined width. The semiconductor substrate 1 is made of semiconductor containing a p-type impurity at a predetermined concentration, such as silicon (Si). Although only two first grooves 2 are shown in FIG. 1A, the number of first grooves 2 is not limited thereto, and the necessary number of first grooves 2 may be formed in the semiconductor substrate 1. The size of the first groove 2 is not limited. According to modern technique, the depth of the first groove 2, which is a basis for a cell transistor to be applied to a DRAM is, for example, approximately 250 nm.

A gate insulating film 3 is formed so as to cover an inner surface of the first groove 2. The gate insulating film 3 is made of an insulator, such as SiO₂ (silicon oxide). A gate electrode 5 is formed over the gate insulating film 3 so as to fill a bottom portion of the first groove 2. The gate electrode 5 is made of a conductor, such as TiN (titanium nitride). A cap insulating film 6 is formed over the gate electrode 5 so as to fill up the first groove 2. Source and/or drain regions 7 and 8 are formed in a surface region of the semiconductor substrate 2 such that the first groove 2 is positioned between the source and/or drain regions 7 and 8. The bottom level of the source and/or drain regions 7 and 8 are lower than the top level of the gate electrode 5. In other words, the top level of the gate electrode 5 is lower than the top level of the semiconductor substrate 2 and higher than the bottom level of the source and/or drain regions 7 and 8. A channel formation region 1a is formed in the semiconductor substrate 2, adjacent to a portion of the gate insulating film 3 which covers bottom and lower-side surfaces of the first groove 2. Thus, a MOS transistor T1 is formed.

The source and/or drain regions 7 and 8 are impurity regions formed by ion implantation of an impurity into the semiconductor substrate 1. A wire 5a connected to the gate electrode 5, and contact electrodes 7a and 8a respectively connected to the source and/or drain regions 7 and 8, are simply shown in FIG. 1A. By controlling a voltage applied to the gate electrode 5A, a channel region can be formed in the semiconductor substrate 1 in the channel formation region 1a, which is adjacent to the portion of the gate insulating film 3 which covers bottom and lower-side surfaces of the first groove 2. Thus, the MOS transistor T1 can control a current that flows between the source and/or drain regions 7 and 8.

Generally, when the semiconductor substrate 1 is a p-type semiconductor substrate, an n-type impurity is ion-implanted to form the source and/or drain regions 7 and 8 so that the MOS transistor T1 becomes an NMOS transistor. When the semiconductor substrate 1 is an n-type semiconductor substrate, a p-type impurity is ion-implanted to form the source and/or drain regions 7 and 8 so that the MOS transistor T1 becomes a PMOS transistor. Any type of MOS transistor structures may be used in the first embodiment. Whichever type of the semiconductor substrate is used, the NMOS or PMOS structure can be formed by ion-implanting an adequate type of an impurity and thus forming an adequate well structure. Therefore, the types of the semiconductor substrate and the type of the MOS transistor structure are not considered in the first embodiment.

For example, when the semiconductor substrate 1 is a p-type semiconductor substrate, the semiconductor substrate 1 contains boron, which is a p-type impurity, at a concentration of 1E16 atoms/cm³ to 1E17 atoms/cm³. On the other hand, the source and/or drain regions 7 and 8 contain any one of or both phosphorus (P) and arsenic (As), which are n-type impurities, at a concentration of 1E19 atoms/cm³ to 1E20 atoms/cm³. Thus, the source and/or drain regions 7 and 8 are n-type semiconductors. In this case, the MOS transistor T1 becomes an n-type MOS transistor. In other words, when a voltage is applied to the gate electrode 5 while a bias voltage is applied between the source and/or drain regions 7 and 8, a channel (n-type inversion layer) is formed in the channel formation region 1a. Then, electrons flow from the source region into the drain region. If the p-impurity is replaced with an n-impurity in the above explanations, the MOS transistor T1 becomes a p-type MOS transistor.

In a region B shown in FIG. 1B in which a compensation capacitor transistor structure is formed, a MOS transistor capacitor T2, which has substantially the same structure as that of the MOS transistor T1 shown in FIG. 1A, is formed.

In other words, multiple second grooves 12 are formed at a predetermined interval in the semiconductor substrate 1. Each second groove 12 has a predetermined depth and a predetermined width. Although the grooves 2 and 12 are illustrated in the same direction for convenience, the extending direction of the second groove 12 in the region B is perpendicular to that of the first groove 2 in the region A in plan view.

A gate insulating film 13 is formed so as to cover an inner surface of the second groove 12. The gate insulating film 13 is made of an insulator, such as SiO₂ (silicon oxide). A gate electrode 15 is formed over the gate insulating film 13 so as to fill a bottom portion of the second groove 12. The gate electrode 15 is made of a conductor, such as TiN (titanium nitride). A cap insulating film 16 is formed over the gate electrode 15 so as to fill up the second groove 12. Source and/or drain regions 17 and 18 are formed in a surface region of the semiconductor substrate 2 such that the second groove 12 is positioned between the source and/or drain regions 17 and 18. The bottom level of the source and/or drain regions 17 and 18 are lower than the top level of the gate electrode 15. In other words, the top level of the gate electrode 15 is lower than the top level of the semiconductor substrate 2 and higher than the bottom level of the source and/or drain regions 17 and 18. A channel formation region 1b is formed in the semiconductor substrate 1, adjacent to a portion of the gate insulating film 13 which covers bottom and lower-side surfaces of the second groove 12. The source and/or drain regions 17 and 18 are shorted. Thus, a MOS transistor capacitor T2 is formed. Although a state in which the source and/or drain regions 17 and 18 are shorted is not shown in FIG. 1B, the source and/or drain regions 17 and 18 are shorted by wires being connected to top portions of the source contact electrode 17a and the drain contact electrode 18a in the first embodiment.

The source and/or drain regions 17 and 18 are impurity regions formed by ion implantation of an impurity into a surface region of the semiconductor substrate 1. A gate wire 15a connected to the gate electrode 15, and contact electrodes 17a and 18a respectively connected to the source and/or drain regions 17 and 18, are simply shown in FIG. 1B.

Similar to the MOS transistor T1 in the region A, the type of the MOS transistor capacitor T2 in the region B (i.e., whether the MOS transistor T2 is a PMOS or NMOS transistor), and the structure type thereof are not considered.

An impurity diffusion region 19 is formed by ion implantation of an impurity into the semiconductor substrate 1, adjacent to a portion of the gate insulating film 13 which covers a bottom portion of the second groove 12. The impurity diffusion region 19 adjusts the channel region 1b of the semiconductor substrate 1, which is adjacent to the portion of the gate insulating film 13 which covers bottom and lower-side surfaces of the second groove 12. Thereby, the impurity diffusion region 19 adjusts a threshold voltage (Vth) of the MOS transistor capacitor 12. To make a threshold voltage of the MOS transistor capacitor T2 being lower than that of the MOS transistor T1 in the first embodiment, when the semiconductor substrate 1 is p-type, an n-type impurity, such as As (arsenic), is ion-implanted into the semiconductor substrate 1 to form an n-type impurity diffusion region. When the semiconductor substrate 1 is an n-type semiconductor substrate, a p-type impurity, such as B (boron), may be ion-implanted into the semiconductor substrate 1 to form a p-type impurity diffusion region in order to adjust the threshold voltage of the MOS transistor capacitor.

The semiconductor substrate 1 of the first embodiment is a p-type silicon substrate. Therefore, an n-type impurity, such as arsenic, is ion-implanted into the region B of the semiconductor substrate 1 (in which the second groove 12 is formed) to adjust the threshold voltage. When the semiconductor substrate 1 is an n-type silicon substrate, however, a p-type impurity, such as boron, may be ion-implanted into the region B of the semiconductor substrate 1 (in which the second groove 12 is formed) to adjust the threshold voltage. The semiconductor substrate 1 may be a semiconductor-based structure, such as a silicon on insulator (SOI), a silicon on sapphire, a doped-type semiconductor substrate, and a semiconductor substrate containing substance other than silicon, such as silicon germanium, germanium, or gallium arsenic.

To make the MOS transistor capacitor T2 in the region B being a compensation capacitor, the source and/or drain regions 17 and 18 are shorted so that one electrode 50 is connected to the gate electrode 15 of the MOS transistor capacitor T2, and the other electrode 51 is connected to the source and/or drain regions 17 and 18 of the MOS transistor capacitor T2, as shown in FIG. 1C. The detailed structure of the other electrode 51 will be explained later. For simplification, an illustration of a wiring structure, in which the source and/or drain regions 17 and 18 are shorted, is omitted in FIG. 1B.

For example, when the semiconductor substrate 1 is a p-type semiconductor substrate, the semiconductor substrate 1 contains boron, which is a p-type impurity, at a concentration of 1E16 atoms/cm³ to 1E17 atoms/cm³. On the other band, the source and/or drain regions 7 and 8 contain any one of or both phosphorus (P) and arsenic (As), which are n-type impurities, at a concentration of 1E19 atoms/cm³ to 1E20 atoms/cm³. Thus, the source and/or drain regions 7 and 8 are n-type semiconductors. Additionally, the impurity diffusion region 19 contains any one of phosphorus (P) and arsenic (As), which are n-type impurities, at a concentration of 5E17 atoms/cm³ to 5E18 atoms/cm³. Thus, the impurity diffusion region 19 is an n-type semiconductor. The source and/or drain regions 17 and 18 are shorted.

In this case, the MOS transistor T2 becomes an n-type MOS capacitor. In other words, the source and/or drain regions 17 and 18 are equipotential since the source and/or drain regions 17 and 18 are shorted. A bias voltage is not applied between the source and/or drain regions 17 and 18. When a voltage is applied to the gate electrode 15, n-type inversion layers are formed in the p-type semiconductor substrate 1, adjacent to the side surfaces of each second groove 12, where the impurity diffusion regions 19 are not formed. Consequently, the source region 17 and the impurity diffusion layer 19 are connected through the n-type inversion layer. Additionally, the drain region 18 and the impurity diffusion layer 19 are connected through the n-type inversion layer. Thus, the source region 17, the n-type inversion layer, the impurity diffusion region 19, the n-type inversion layer, and the drain region 18 are all connected to become equipotential, thus forming one plate electrode. This plate electrode becomes the aforementioned other electrode 51. Accordingly, the n-type MOS capacitor of the first embodiment includes: the gate electrode 15 as one electrode 50; the gate insulating film 13 as the capacitor insulating film; and the plate electrode as the other electrode 51. If the p-type impurity is replaced with an n-type impurity in the above explanations, the MOS transistor T2 becomes a p-type MOS capacitor.

Hereinafter, one of the methods is explained in which the impurity diffusion region 19 is formed by ion implantation of an impurity without providing an additional process of forming a mask, when the regions A and B shown in FIGS. 1A and 1B are formed.

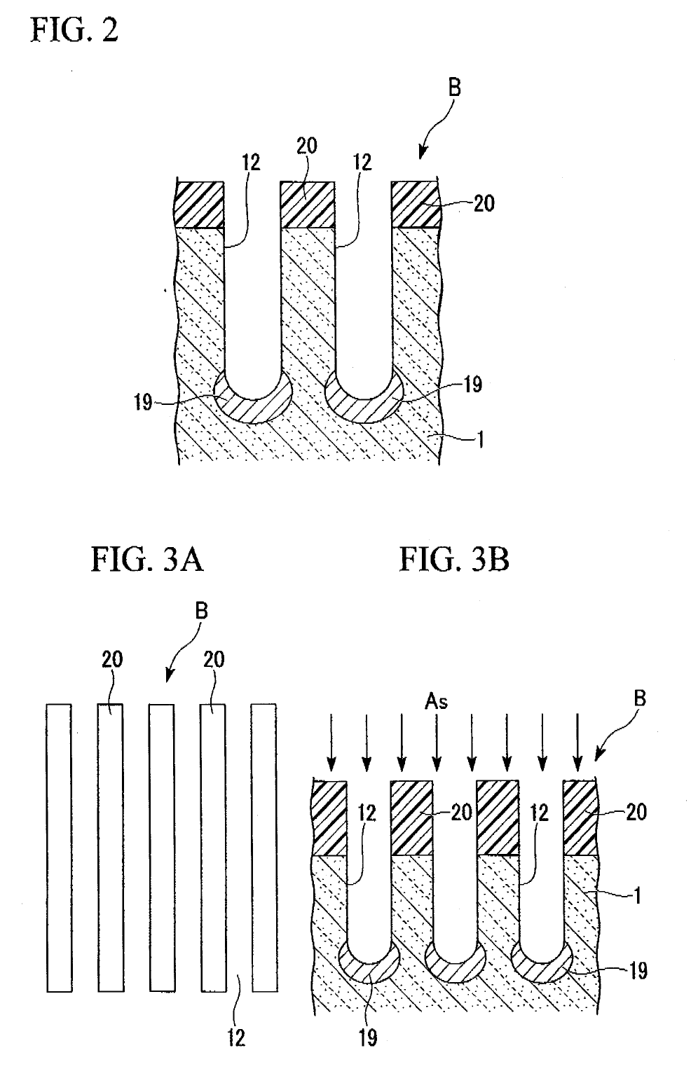

As shown in FIG. 2, a mask 20 for forming the second groove 12 in the region B is formed over the semiconductor substrate 1. Then, the mask 20 is patterned by a photolithography process. Then, multiple second grooves 12 are formed in the semiconductor substrate 1 by an etching process with the patterned mask 20. The second grooves 12 are formed at a predetermined interval. Each second groove 12 has a predetermined width. Then, an n-type impurity, such as arsenic, is ion-implanted into portions of the semiconductor substrate 1 under the second grooves 12. Thus, the impurity diffusion region 19 is formed.

In the etching process of forming the second grooves 12, the mask 20 in the region B is formed so as to have a line-and-space pattern extending in a first direction, as shown in FIG. 3A. The line portions of the mask 20 are arranged at a predetermined interval. Each line portion has a predetermined width. Further, the mask 21 in the region A is formed so as to have a line-and-space pattern extending in a second direction that is perpendicular to the first direction. The line portions of the mask 21 are arranged at a predetermine interval. Each line portion has a predetermined width. In other words, the line portions of the mask 20 in the region B are perpendicular to the line portions of the mask 21 in plan view.

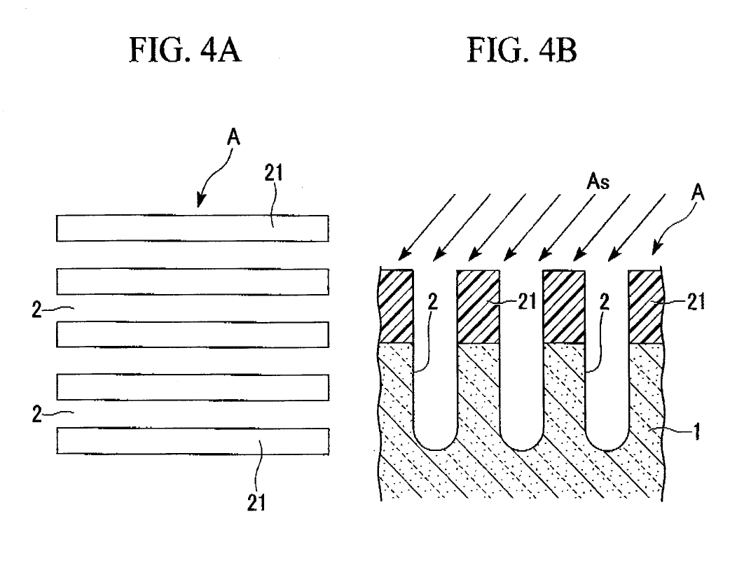

After the grooves 2 and 12 are formed, an n-type impurity, such as arsenic, is ion-implanted into the region B of the semiconductor substrate 1 in a direction parallel to an extending direction of the second groove 12 (i.e., a depth direction thereof), as indicated by arrows shown in FIG. 3B. At the same time, the n-type impurity is ion-implanted into the region A of the semiconductor substrate 1 in a direction oblique to an extending direction of the first groove 2, as indicated by arrows shown in FIG. 4B. At this time, in the region B, the ions can reach the semiconductor substrate 1 under the bottom portion of the second groove 12, as shown in FIG. 3B. In the region A, however, the ions are blocked by the mask 21 and cannot reach the semiconductor substrate 1 under the bottom portion of the first groove 2, as shown in FIG. 4B. Therefore, the implantation of the ions does not affect the MOS transistor T1 in the region A.

When ions are irradiated to the semiconductor substrate 1 in a direction that is 45 degrees oblique to the side surface of the second groove 2 as shown in FIG. 4B, the thicknesses of the masks 20 and 21 are preferably larger than the width of the first groove 2. It is preferable to determine the thicknesses of the mask 20 and 21 according to the radiation angle of ions so that the ions cannot reach the bottom surface of the first groove 2 in the region A. For this reason, it is preferable to select the relationship among an angle at which the grooves 2 and 12 cross each other, the thicknesses of the masks 20 and 21, and the depths of the grooves 2 and 12, such that ions reach the bottom surface of the second groove 12, but cannot reach the bottom surface of the first groove 2.

In the ion implantation process of the first embodiment, ions are irradiated to the region B of the semiconductor substrate 1 (in which the second groove 12 is formed) at an incident angle of approximately 90 degrees, as shown in FIG. 3B. On the other hand, ions are irradiated to the region A of the semiconductor substrate 1 (in which the first groove 2 is formed) at an incident angle of approximately 45 degrees, as shown in FIG. 4B.

The crossing angle of the first and second grooves 2 and 12 in plan view is not limited to 90 degrees. It is preferable to select, according to an ion incident angle, a crossing angle in a range such that ions can reach the bottom surface of the second groove 12 in the region B, and cannot reach the bottom surface of the first groove 2.

As explained above, the structure, in which the impurity diffusion region 19 is formed only in the region B of the semiconductor substrate 1 while ions are not implanted into the region A of the semiconductor substrate 1 under the bottom surface of the first groove 2, can be formed by ion irradiation at an oblique angle with respect to the region A without providing an additional process of forming masks.

After the ion irradiation process, the gate insulating films 3 and 13, the gate electrodes 5 and 15, and the cap insulating films 6 and 16 are sequentially formed. Then, the impurity diffusion regions 7, 8, 17, and 18 are formed by ion implantation. Thus, the MOS transistor T1 and the MOS transistor capacitor T2 can be formed on the semiconductor substrate 1, as shown in FIGS. 1A and 1B.

After the MOS transistor T1 and the MOS transistor capacitor T2 are formed, the gate electrode 15 of the MOS transistor capacitor T2 is connected to the source and/or drain regions 17 and 18, as shown in FIG. 1C. Thus, the MOS transistor capacitor T2 having a large capacitance can be formed.

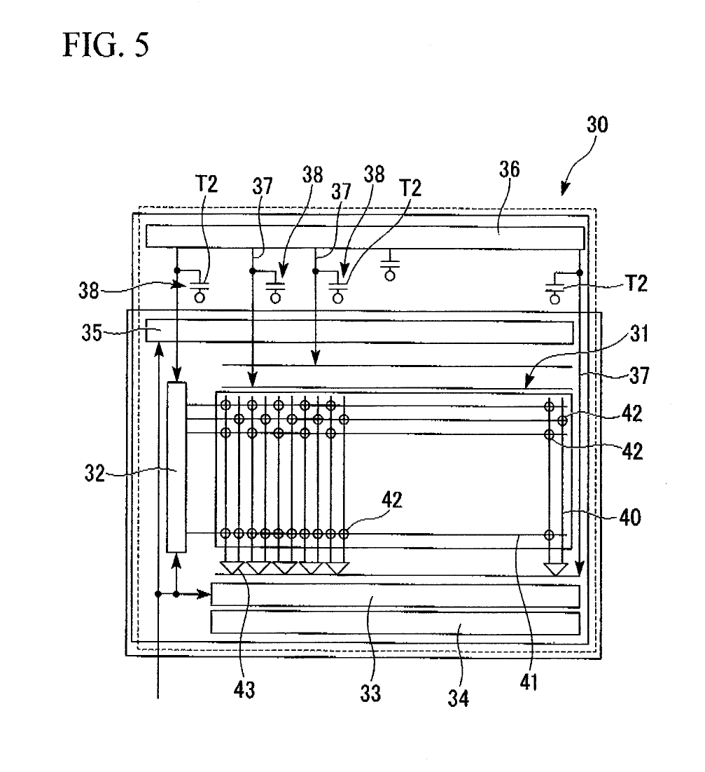

FIG. 5 is a circuit block diagram illustrating an example of a DRAM 30 as a semiconductor device, which actually includes the MOS transistor T1 and the MOS transistor capacitor T2 shown in FIGS. 1A to 1C.

The DRAM 30 of the first embodiment includes: a cell array unit 31; an X decoder 32 and a Y decoder, which are connected to the cell array unit 31; a buffer 34; a timing generator 35; an internal power circuit 36; a circuit wire 37 connecting the internal power circuit 36 and the cell array 31; and a compensation capacitor 38 connected to the circuit wire 37.

In the cell array unit 31, a cell array 42 is positioned at the intersection of a bit line 40 with a word line 41. In each cell array 42, the MOS transistor T1 of the first embodiment and a DRAM capacitor (not shown) are provided. A reference numeral 43 denotes a sense amplifier connected to the bit line 40.

The MOS transistor capacitor T2 shown in FIGS. 1B and 1C are used as the compensation capacitor 38 connected to the circuit wire 37 connecting the internal power circuit 36 and the cell array unit 31. The MOS transistor capacitor T2 stabilizes power supply from the internal power circuit 36 with the capacitance of the MOS transistor capacitor T2.

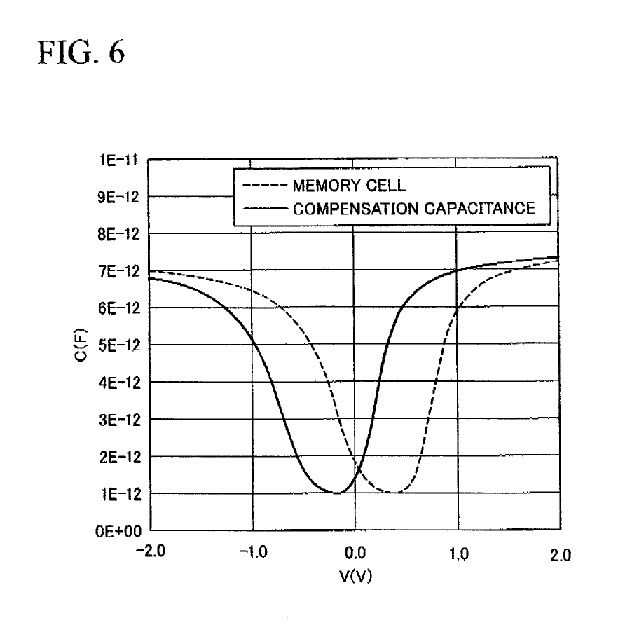

FIG. 6 is a graph illustrating a VC curve for the MOS transistor T1 shown in FIG. 1A and the MOS transistor capacitor T2 shown in FIG. 1B. As can be understood from FIG. 6, if arsenic is implanted into a channel region of a MOS transistor on the side of a compensation capacitor when a p-type semiconductor substrate is used to form the same structured trench MOS transistor, the VS curve shifts to the left, and thereby the threshold voltage is decreased.

In other words, it can be understood that a sufficient capacitance of MOS transistor capacitor T2 shown in FIG. 1B can be achieved compared to the MOS transistor T1 in the memory cell, even in the low voltage range of 0.5 V to 1.0 V.

In the compensation capacitor of the first embodiment, the C (capacitance) becomes 7E-12F or more when V (voltage) is 1 V or more. However, C is decreased down to 1E-12F when V is 0 V, as shown in FIG. 6. Since a voltage difference, such as approximately 0.5 V to 1 V, is generally applied to an actual DRAM circuit, the compensation capacitor can achieve the capacitance of approximately 5E-12F at the voltage of 0.5 V. On the other hand, the MOS transistor, which is included in a memory cell portion including no impurity diffusion region, has capacitance of only approximately 1E-12F.

FIG. 6 shows that the VC curve of the MOS transistor capacitor 12 shown in FIG. 6 shifts to the left side when the threshold voltage is low. For this reason, the fact that a threshold voltage of the first embodiment is low indicates that a sufficient capacitance value can be obtained even if the threshold value is reduced to the range of approximately 0.5 V to 1.0 V. Accordingly, the MOS transistor capacitor T2 of the first embodiment obtains a larger capacitance value than in the case where a MOS transistor having the exact same structure as that of the MOS transistor in the memory cell is used as a compensation capacitor.

When a threshold voltage of the MOS transistor T1 in the memory cell 31 of a general DRAM structure is assumed to be approximately 0.65 V, the threshold voltage of the MOS transistor capacitor T2 can be approximately 0.5 V by forming an impurity diffusion region in the channel region of the MOS transistor capacitor T2. In other words, a DRAM, in which the threshold voltage of the MOS transistor capacitor T2 is lower than that of the MOS transistor T1, can be provided.

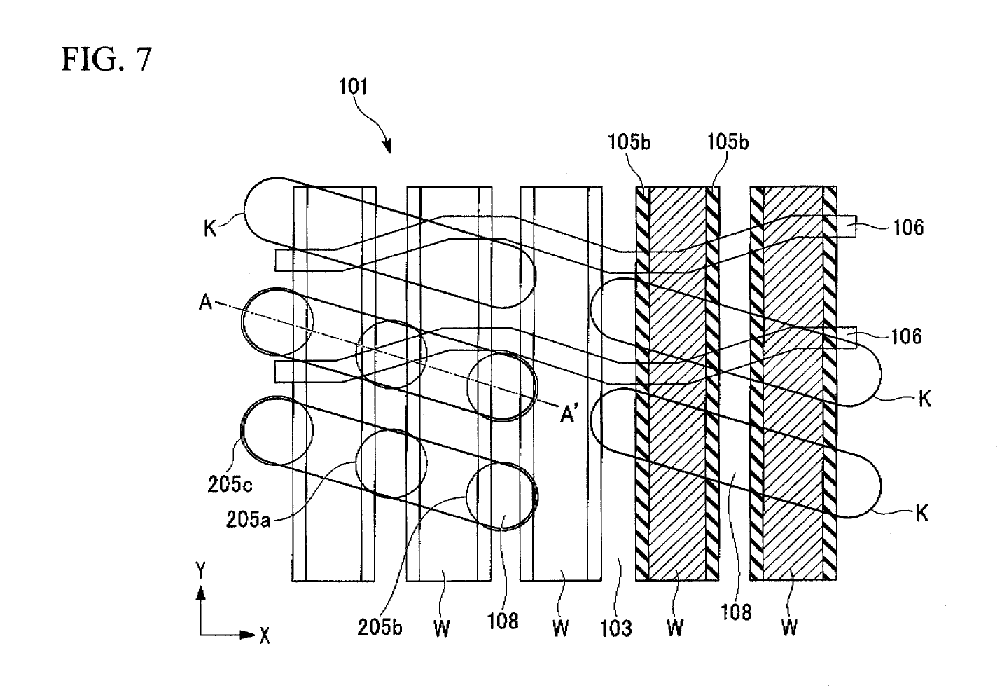

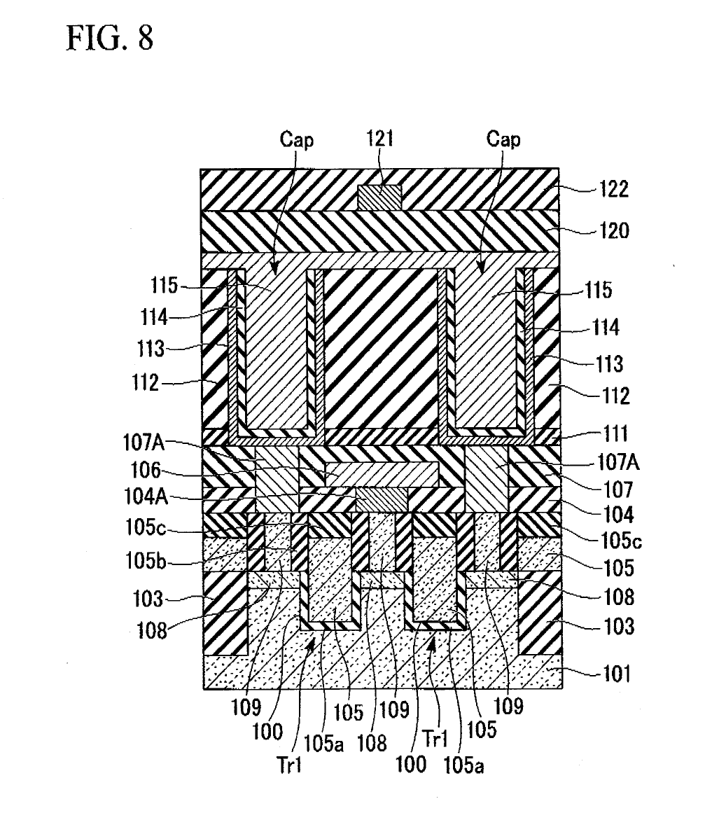

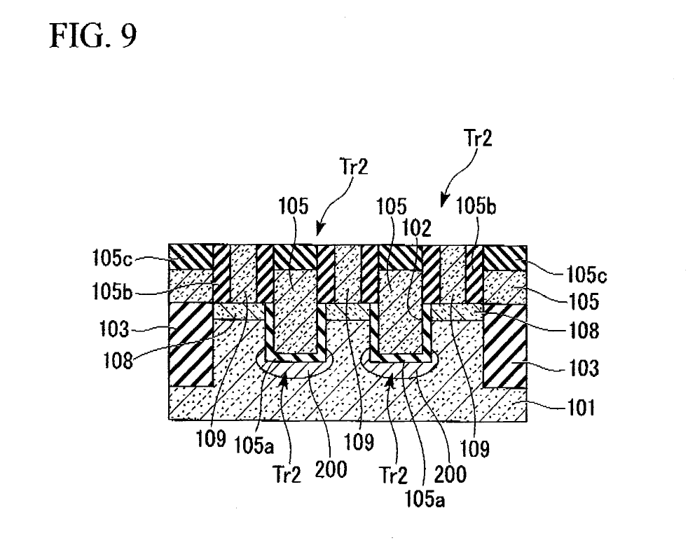

Hereinafter, the DRAM 30 of the first embodiment is explained in detail. FIG. 7 is a plan view illustrating part of a cell structure of the DRAM 30 of the first embodiment. Specifically, FIG. 7 is a plan view illustrating an example of layout of the memory cell portion. The right side (in the X direction) of FIG. 7 is a transparent view illustrating a cross-section taken along a plan, cutting the gate electrode 105 (that will be the word line W) and a sidewall 105b. FIG. 8 is a cross-sectional view taken along line A-A′ shown in FIG. 7, and illustrates a cross-sectional structure of a semiconductor memory device. FIG. 9 is a cross-sectional view illustrating a cross-sectional structure of the compensation capacitor.

Parts of the cell structure of the DRAM 30 shown in FIG. 5 correspond to the structures shown in FIGS. 7 and 8. Part of the structure of the compensation capacitor 38 shown in FIG. 5 corresponds to the structure shown in FIG. 9.

Firstly, the memory cell portion is explained with reference to FIG. 7. The memory cell portion includes: a bit wire 106 extending in the X direction; a word wire W extending in the Y direction; an active region K that has a narrow strip shape; and an impurity diffusion layer 108.

The bit wire 106 has a curved-line shape extending in the X direction. Multiple bit wires 106 are arranged in the Y direction at a predetermined interval. The word wire W has a straight line shape extending in the Y direction. Multiple word wires W are arranged at a predetermined interval in the X direction. The gate electrode 105 (not shown in FIG. 7), which will be explained later, is positioned at the intersection of the word wire W with each active region K. The sidewalls 105b extending in the Y direction are formed on both sides of the word wire W.

The active regions K are formed on a surface of the semiconductor substrate 101. The active regions K have a strip shape, and are arranged in the lower-right direction based on the layout of so called the 6F2 memory cell structure. The impurity diffusion layers 108 are formed on the center and both side portions of the active region K. The impurity diffusion layer 108 functions as a source and/or drain region of a MOS transistor Tr1 as will be explained later. The circular substrate contact portions 205a, 205b, and 205c are formed above the source and/or drain regions (impurity diffusion regions).

The center of each substrate contact portion 205a, 205b, and 205c is positioned between the word wires W. The center substrate contact portion 205a overlaps the bit wire 106 in plan view. The substrate contact portions 205a, 205b, and 205c are arranged at positions of substrate contact plugs 109 that will be explained later. The substrate contact portions 205a, 206b, 205c are in contact with the semiconductor substrate 101.

Hereinafter, the memory cell portion is explained with reference to FIG. 8. The memory cell portion of the DRAM 30 of the first embodiment includes: a MOS transistor Tr1; a substrate contact plug 109 and a capacitor contact plug 107A that are connected to the MOS transistor Tr1; and a capacitor element Cap that is formed over the capacitor contact plug 107A and includes a multi-layered film including a metal oxide film, as a capacitor insulating film 114.

The MOS transistor Tr1 of the first embodiment includes: a semiconductor substrate 101; a device isolation region 103 in the semiconductor substrate 101; an active region K defined by the device isolation region 103; and two trench gate electrodes 105 in the active region K.

The semiconductor substrate 101 is made of semiconductor containing a p-type impurity at a predetermined concentration, such as silicon (Si). The device isolation region 103 is formed in the semiconductor substrate 101. The device isolation region 103 is formed by forming a groove in the semiconductor substrate 1 and then filling the groove with an insulating film, such as a silicon oxide (SiO₂) film. Thus, adjacent active regions K are separated by the device isolation region 103.

One active region K of the semiconductor substrate 101 is divided by two trench gate electrodes 105 into three portions. Then, source and/or drain regions 108 are formed in the surface regions of the divided three portions of the semiconductor substrate 101. For example, an n-type impurity, such as phosphorus (P), is diffused in the source and/or drain region 108.

The gate electrode 105 is a trench gate electrode. The gate electrode 105 is buried in a first groove 100 formed in the semiconductor substrate 101. The gate electrode 105 protrudes from the top surface of the semiconductor substrate 101.

The gate electrode 105 is made of a multi-layered film including a polycrystalline silicon film containing an impurity, and a metal film. The polycrystalline silicon film can be formed by introducing an n-type impurity, such as phosphorus (P), into a silicon film when the silicon film is formed by a CVD (Chemical Vapor Deposition) method. The aforementioned metal film includes a high melting point metal, such as tungsten (W), tungsten nitride (WN), or tungsten silicide (WSi). Thus, the two gate electrodes 105 function as two MOS transistors Tr1.

The gate insulating film 105a is formed so as to cover an inner surface of the first groove 100. The gate electrode 105 is formed over the gate insulating film 105a so as to fill up the first groove 100. The gate electrode 105 includes a protruding portion extending upwardly from the upper surface of the semiconductor substrate 101. The sidewall 105b is formed so as to cover side surfaces of the protruding portion of the gate electrode 105. The sidewall 105b is made of an insulating film, such as a silicon nitride (Si₃N₄) film. A cap insulating film 105c, which is made of a silicon nitride film or the like, is formed over the gate electrode 105 in order to protect the upper surface of the gate electrode 105.

The substrate contact plug 109 is formed so as to be in contact with the source and/or drain region 108. The positions of the substrate contact plugs 109 correspond to those of the substrate contact portions 205c, 205a, and 205b shown in FIG. 7. The substrate contact plug 109 is made of for example, polycrystalline silicon containing phosphorus (P). The width of the substrate contact plug 109 in the X direction is defined by the sidewalls 105b. The substrate contact plug 109 has a self-alignment structure.

An inter-layer insulating film 104 is formed so as to cover an insulating film 105c over the gate electrode 105. The position of the bit contact plug 104A corresponds to the position of the substrate contact portion 205a shown in FIG. 7. The bit contact plug 104A penetrates through the inter-layer insulating film 104 and is electrically communicated with the substrate contact plug 109. The bit contact plug 104A is formed by forming a tungsten (W) film cover a bather film (TiN/Ti) including a titanium (Ti) film and a titanium nitride (TiN) film.

A bit wire 106 is formed so as to be connected to the bit contact plug 104A. The bit wire 106 is made of a multi-layered film including a tungsten (WN) nitride film and a tungsten (W) film.

A second inter-layer insulating film 107 is formed so as to cover the bit wire 106 and the inter-layer insulating film 104. A capacitor contact plug 107A is formed so as to penetrate through the second inter-layer insulating film 107 and the inter-layer insulating film 104 and to be connected to the substrate contact plug 109. The positions of the capacitor contact plugs 107A correspond to the positions of the substrate contact portions 205b and 205c.

A third inter-layer insulating film 111, which is made of a silicon nitride film, is formed so as to cover the second inter-layer insulating film 107. A fourth inter-layer insulating film 112, which is made of a silicon oxide film, is formed so as to cover the third inter-layer insulating film 111.

The capacitor element Cap penetrates through the third and fourth inter-layer insulating films 111 and 112 so that a lower electrode 113 is connected to the capacitor contact plug 107A. The capacitor element Cap includes: the lower electrode 113; a capacitor insulating film 114 covering the lower electrode 113; and an upper electrode 115 covering the capacitor insulating film 114. The capacitor insulating film 114 is made of a multi-layered film including metal oxide films, which is formed by the aforementioned method of forming the MOS transistor T1 and the MOS transistor capacitor T2. The lower electrode 113 is connected to the MOS transistor Tr1 through the capacitor contact plug 107A.

A fifth inter-layer insulating film 120 is formed over the upper electrode 115. A wire 121 is formed over the fifth inter-layer insulating film 120. A surface protection film 122 is formed so as to cover the fifth inter-layer insulating film 120 and the wire 121. The fifth inter-layer insulating film 120 is made of silicon oxide or the like. The wire 121 is made of aluminum (AI), copper (Cu), or the like.

A predetermined voltage is applied to the upper electrode 115 of the capacitor element Cap. Therefore, presence and absence of electric charge stored in the capacitor element Cap is determined, and thereby the MOS transistor Tr1 can function as a DRAM that stores information.

FIG. 9 illustrates an example of a MOS transistor capacitor Tr2 that is a compensation capacitor. Like reference numerals denote like elements between FIGS. 8 and 9, and explanations thereof are omitted here. The MOS transistor capacitor Tr2 shown in FIG. 9 differs from the MOS transistor Tr1 in that an impurity diffusion region 200 is formed in a channel formation region, adjacent to a portion of the gate insulating film 105a which covers the bottom portion of a second groove 102. The extending direction of the second groove 102 of the MOS transistor capacitor Tr2 is perpendicular to that of the first groove 100 of the MOS transistor Tr1 in plan view.

The two source and/or drain regions 108 are connected to each other to be used as one electrode, and the gate electrode 105 is used as another electrode, as shown in FIG. 1C. Thus, the MOS transistor capacitor Tr2, which becomes a compensation capacitor, is formed. For example, the MOS transistor capacitor Tr2 is connected to a wire connecting the internal power circuit 36 and the memory cell 31 in order to stabilize the voltage of the internal power circuit 36, as shown in FIG. 5.

The threshold voltage of the MOS transistor capacitor Tr2 shown in FIG. 9 is set to be lower than that of the MOS transistor Tr1 shown in FIGS. 7 and 8, in a similar manner as in the first embodiment. Accordingly, a capacitor value of the MOS transistor capacitor Tr2 as a compensation capacitor can be increased, thereby achieving stabilization of power voltage.

As explained above, according to the semiconductor device of the first embodiment, in the trench-gate-type compensation capacitor transistor structure T2, the impurity diffusion region 19 is formed in the channel region 1b adjacent to a portion of the gate insulating film 13 which covers a bottom portion of the second groove 12, so that the threshold voltage of the compensation capacitor transistor structure T2 becomes lower than the threshold voltage of the main transistor structure T1. Accordingly, even when the transistor structure T2 is used as a compensation capacitor, a large compensation capacitance value can be achieved. Therefore, for example, the compensation capacitance transistor structure T2 can achieve stabilization of the voltage when used as a voltage compensation capacitor included in a built-in voltage generation circuit.

According to the method of manufacturing the semiconductor device of the first embodiment, the first groove 2 and the second groove 12 are formed in the semiconductor substrate 1 with masks 20 and 21 so that the first and second grooves 2 and 12 cross each other in plan view. Then, with use of the masks 20 and 21 used for forming the first and second grooves 2 and 12, an ion is irradiated vertically with respect to the second groove 12 while the ion is irradiated obliquely with respect to the first groove 2. Consequently, the ion can reach a bottom surface of the second groove 12, but cannot reach a bottom surface of the first groove 2. Accordingly, without providing an additional process of forming another photomask, an ion can be selectively implanted into the semiconductor substrate 1 on the side of the compensation capacitor transistor structure T2 to form the impurity diffusion region 19 in the channel region 1b of the compensation capacitor transistor structure T2.

Therefore, the threshold voltage of the compensation capacitor transistor structure T2 can be lower than that of the main transistor structure T1 without providing another photomask, thereby achieving a larger capacitance value of the compensation capacitor transistor structure T2.

As used herein, the following directional terms “forward,” “rearward,” “above,” “downward,” “vertical,” “horizontal,” “below,” and “transverse,” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, and may be modified and changed without departing from the scope and spirit of the invention.

In addition, while not specifically claimed in the claim section, the application reserves the right to include in the claim section at any appropriate time the following method.

A method of manufacturing a semiconductor device may include, but is not limited to the following processes. A first groove is formed in a semiconductor substrate. A second groove, which crosses the first groove in plan view, is formed in the semiconductor substrate. A first impurity is introduced over the first groove at a first incident angle to a surface of the semiconductor substrate while the first impurity is introduced over the second groove at a second incident angle to the surface of the semiconductor substrate. The second incident angle is different from the first incident angle.

What is claimed is:

1. A semiconductor device comprising:
a semiconductor substrate having first and second grooves crossing each, other in plan view;
a first insulating film covering an inner surface of the first groove;
a second insulating film covering an inner surface of the second groove;
a first gate electrode filling at least a bottom portion of the first groove;
a second gate electrode filling at least a bottom portion of the second groove; and
a first semiconductor region in the semiconductor substrate, the first semiconductor region containing a first impurity, the first semiconductor region being adjacent to a first portion of the second insulating film, and the first portion of the second insulating film covering at least a bottom region of the second groove.

2. The semiconductor device according to claim 1, wherein
the first insulating film has a first portion that covers at least a bottom region of the first groove, and
the first portion of the first insulating film is adjacent to the semiconductor substrate.

3. The semiconductor device according to claim 1, wherein
the first insulating film isolates the first gate electrode from the semiconductor substrate, and
the second insulating film isolates the second gate electrode from the first semiconductor region and the semiconductor substrate.

4. The semiconductor device according to claim 1, wherein
the first groove extends in a first direction, and
the second groove extends in a second direction that is different from the first direction.

5. The semiconductor device according to claim 1, wherein the first semiconductor region and the semiconductor substrate have different conductivity types.

6. The semiconductor device according to claim 1, wherein
the semiconductor substrate has a first impurity concentration, and
the first semiconductor region has a second impurity concentration that is greater than the first impurity concentration.

7. The semiconductor device according to claim 1, further comprising:
a second semiconductor region in the semiconductor substrate, the second semiconductor region containing a second impurity, the second semiconductor region being adjacent to a surface of the semiconductor substrate and the first insulating film, and
a third semiconductor region in the semiconductor substrate, the third semiconductor region containing a third impurity, the third semiconductor region being adjacent to the surface of the semiconductor substrate and the second insulating film.

8. The semiconductor device according to claim 7, wherein
the first semiconductor region and the semiconductor substrate have different conductivity types, and
the first to third semiconductor regions have the same conductivity type.

9. The semiconductor device according to claim 7, further comprising:
a first channel region in the semiconductor substrate, the first channel region being adjacent to a second portion of the first insulating film, the second portion of the first insulating film covering lower side and bottom surfaces of the first groove, and the first channel region being connected to the second semiconductor region; and
a second channel region in the semiconductor substrate, the second channel region being adjacent to a second portion of the second insulating film, the second portion of the second insulating film covering lower side surfaces of the second groove, and the second channel region connecting the first and third semiconductor regions.

10. The semiconductor device according to claim 7, wherein
the top level of the first gate electrode is lower than the top level of the semiconductor substrate and higher than the bottom level of the second semiconductor region, and
the top level of the second gate electrode is lower than the top level of the semiconductor substrate and higher than the bottom level of the third semiconductor region.

11. The semiconductor device according to claim 1, further comprising:
a third insulating film over the first gate electrode, the third insulating film filling up the first groove; and
a fourth insulating film over the second gate electrode, the fourth insulating film filling up the second groove.

12. The semiconductor device according to claim 1, wherein
the first gate electrode ells up the first groove, and
the second gate electrode fills up the second groove.

13. The semiconductor device according to claim 12, wherein
the first gate electrode comprises a first protruding portion extending upwardly from the semiconductor substrate,
the second gate electrode comprises a second protruding portion extending upwardly from the semiconductor substrate, and
the semiconductor device further comprises:
a first sidewall covering a side surface of the first protruding portion; and
a second sidewall covering a side surface of the second protruding portion.

14. A semiconductor device comprising:
a semiconductor substrate having a memory cell region and a peripheral region;
a first transistor structure over the memory cell region, the first transistor structure comprising a first trench gate electrode in the memory cell region;
a second transistor structure over the peripheral region, the second transistor structure comprising:
a second trench gate electrode in the peripheral region;
a first semiconductor region in the peripheral region, the first semiconductor region containing a first impurity, the first semiconductor region being adjacent to a surface of the semiconductor substrate and the second trench gate electrode;
a second semiconductor region in the peripheral region, the second semiconductor region containing a second impurity, the second semiconductor region being adjacent to the surface of the semiconductor substrate and the second trench gate electrode, the second trench gate electrode being positioned between the first and second semiconductor regions; and
a third semiconductor region in the semiconductor substrate, the third semiconductor region containing a third impurity, the third semiconductor region being adjacent to a bottom portion of the second trench gate electrode.

15. The semiconductor device according to claim 14, wherein
the first to third semiconductor regions have the same conductivity type, and
the third semiconductor region and the semiconductor substrate have different conductivity types.

16. The semiconductor substrate according to claim 14, wherein
the first semiconductor region contains the first impurity at a first concentration,
the second semiconductor region contains the second impurity at a second concentration,
the third semiconductor region contains the third impurity at a third concentration that is greater than the first and second concentrations, and
the semiconductor substrate contains a fourth impurity at a fourth concentration that is smaller than the first and second concentrations.

17. The semiconductor device according to claim 14, wherein
the first transistor structure has a first threshold voltage, and
the second transistor structure has a second threshold voltage that is smaller than the first threshold voltage.

18. A semiconductor device comprising:
a semiconductor substrate having a groove;
an insulating film covering an inner surface of the groove;
a gate electrode filling at least a bottom portion of the groove; and
a first semiconductor region in the semiconductor substrate, the first semiconductor region containing a first impurity, the first semiconductor region being adjacent to a surface of the semiconductor substrate and the gate electrode;
a second semiconductor region in the semiconductor substrate, the second semiconductor region containing a second impurity, the second semiconductor region being adjacent to the surface of the semiconductor substrate and the gate electrode, the gate electrode being positioned between the first and second semiconductor regions;
a third semiconductor region in the semiconductor substrate, the third semiconductor region containing a third impurity, the third semiconductor region being adjacent to a first portion of the insulating film, the first portion covering at least a bottom region of the groove; and
a channel region in the semiconductor substrate, the channel region being adjacent to a second portion of the insulating film, the second portion covering lower side surfaces of the groove, and the channel region connecting the first to third semiconductor regions.

19. The semiconductor device according to claim 18, wherein
the first to third semiconductor regions have the same conductivity type, and
the third semiconductor region and the semiconductor substrate have different conductivity types.

20. The semiconductor substrate according to claim 18, wherein
the first semiconductor region contains the first impurity at a first concentration,
the second semiconductor region contains the second impurity at a second concentration,
the third semiconductor region contains the third impurity at a third concentration that is greater than the first and second concentrations, and
the semiconductor substrate contains a fourth impurity at a fourth concentration that is smaller than the first and second concentrations.
